(19) United States
(12) Patent Application Publication
(10) Pub. No.: US 2026/0316110 A1
(43) Pub. Date: Oct. 15, 2026

(54) LITHIUM COATING VIA KISS ROLLERS

(71) Applicant: Applied Materials, Inc., Santa Clara, CA (US)

(72) Inventors: Terry Bluck, Santa Clara, CA (US); Subramanya P. Herle, Mountain View, CA (US)

(21) Appl. No.: 19/482,681

(22) PCT Filed: May 8, 2024
(86) PCT No.: PCT/US2024/028413

§ 371 Date: Nov. 7, 2025

Related U.S. Application Data
(60) Provisional application No. 63/465,784, filed on May 11, 2023.

(51) Int. Cl. B05C 1/08; B05C 1/10; C23C 26/02; H01M 4/04

(52) U.S. Cl. CPC B05C 1/0808; B05C 1/0813; B05C 1/0817; B05C 1/10; C23C 26/02; H01M 4/0402

(57) ABSTRACT

In one aspect, a roll-to-roll vacuum coating system is provided. The roll-to-roll vacuum coating system includes a substrate, a first evaporation assembly, and a kiss roller assembly. The kiss roller assembly includes a kiss roller with a thermal conductivity of less than or equal to 30 W/m-K, a second evaporation assembly, and at least one retractable roller.

### BACKGROUND

### Field

The present disclosure generally relates to a roll-to-roll vacuum coating system with a kiss roller assembly for a deposition process. More particularly, the present disclosure generally relates to a kiss roller assembly design and methods, which provide a uniform deposition layer.

### Description of the Related Art

The deposition of thin lithium coatings (e.g., greater than 1 um) is used to make anodes for batteries, such as lithium ion batteries. However, suitable anode substrates (e.g., copper, graphite, silicon, or combination thereof) may overheat from current techniques used for depositing such thin coatings. Deposition techniques include the use of molten lithium and/or thermal evaporators. Such deposition techniques, can very easily overheat a relatively cold substrate (e.g., less than or equal to 100 degrees Celsius) and have difficulty controlling the thickness of such thin coatings.

Thus, there is a need for methods and systems for reducing the thermal load on substrates during deposition processes.

### SUMMARY

In one aspect, a roll-to-roll vacuum coating system is provided. The roll-to-roll vacuum coating system includes a substrate, a first evaporation assembly, and a kiss roller assembly. The kiss roller assembly includes a kiss roller with a thermal conductivity of less than or equal to 30 W/m-K, a second evaporation assembly, and at least one retractable roller.

In another aspect, a method for depositing material on a substrate in a roll-to-roll vacuum system is provided. The method includes depositing a first layer with a first thickness on a substrate via a first evaporation assembly, evaporating a fluid onto a kiss roller via a second evaporation assembly, and depositing a second layer with a second thickness on the substrate via the kiss roller, the second thickness greater than the first thickness.

In yet another aspect, a roll-to-roll vacuum coating system is provided. The roll-to-roll vacuum coating system includes a substrate, an evaporation assembly, and a kiss roller assembly. The kiss roller assembly includes a porous kiss roller and at least one retractable roller.

In yet another aspect, a method for depositing material on a substrate in a roll-to-roll vacuum system is provided. The method includes depositing a first layer with a first thickness on a substrate via an evaporation assembly and depositing a second layer with a second thickness on the substrate via the porous kiss roller, the second thickness greater than the first thickness.

In yet another aspect, a roll-to-roll vacuum coating system is provided. The roll-to-roll vacuum coating system includes a substrate, an evaporation assembly, and a kiss roller assembly. The kiss roller assembly includes an engraved kiss roller with engraved portions, a molten fluid bath, and at least one retractable roller.

In yet another aspect, a method for depositing material on a substrate in a roll-to-roll vacuum system is provided. The method includes depositing a first layer with a first thickness on a substrate via an evaporation assembly, rotating an engraved kiss roller with engraved portions through a molten fluid bath, and depositing a second layer with a second thickness on the substrate via the engraved kiss roller, the second thickness greater than the first thickness.

### BRIEF DESCRIPTION OF THE DRAWINGS

So that the manner in which the above-recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 illustrates a schematic side view of a kiss roller assembly having an evaporation assembly and a kiss roller according to one or more embodiments.

FIG. 2 illustrates a method for depositing material on a substrate in a roll-to-roll vacuum system according to one or more embodiments.

FIG. 3 illustrates a schematic side view of a kiss roller assembly having a porous kiss roller according to one or more embodiments.

FIG. 4 illustrates a method for depositing material on a substrate in a roll-to-roll vacuum system according to one or more embodiments.

FIG. 5 illustrates a schematic side view of a kiss roller assembly having an engraved kiss roller according to one or more embodiments.

FIG. 6 illustrates a method for depositing material on a substrate in a roll-to-roll vacuum system according to one or more embodiments.

FIG. 7A-7B illustrate a schematic side view of a kiss roller assembly having two retractable rollers according to one or more embodiments.

FIG. 7C-7D illustrate a schematic side view of a kiss roller assembly having one retractable roller according to one or more embodiments.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

Reference will now be made in detail to the various implementations of the present disclosure, one or more examples of which are illustrated in the Figures. Within the following description of the drawings, the same reference numbers refer to the same components. Generally, only the differences with respect to individual implementations are described. Each example is provided by way of explanation of the present disclosure and is not meant as a limitation of the present disclosure. Further, features illustrated or described as part of one implementation can be used on or in conjunction with other implementations to yield yet a further implementation. It is intended that the description includes such modifications and variations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

As utilized herein, the term “on” is inclusive of both direct and indirect embodiments. That is to say the term “on,” as used herein, may mean both “directly on (and in contact with) as well as “disposed over (without direct contact).”

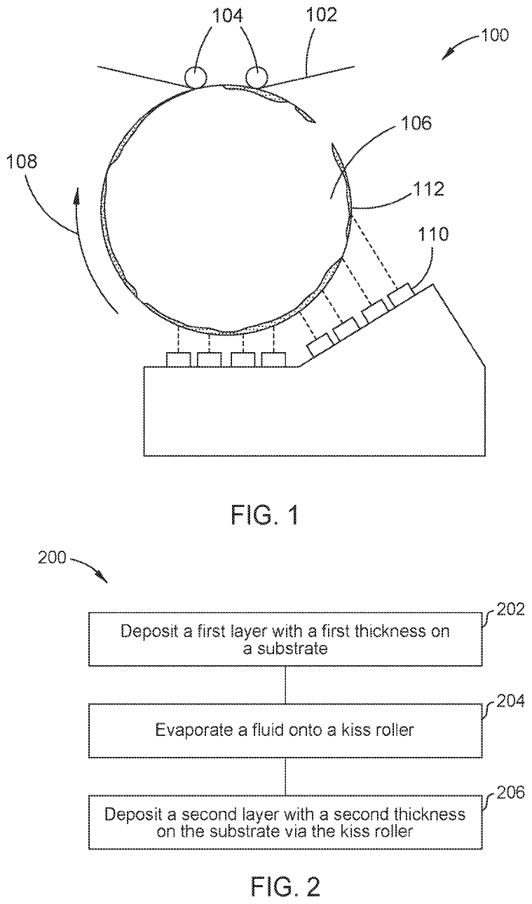

FIG. 1 illustrates a schematic side view of a kiss roller assembly 100 having one or more evaporation assemblies 110 and a kiss roller 106 according to one or more embodiments. The kiss roller assembly 100 can be part of a roll-to-roll system adapted for depositing coatings on web materials, for example, for depositing metal containing film stacks according to the implementations described herein. In one or more examples, the kiss roller assembly 100 can be used for depositing elemental metals, metal alloys, and/or other elements. Examples of metal elements, metal alloys, and other elements can be or include alkali metals (e.g., lithium or sodium), alkaline earth metals (e.g., magnesium or beryllium), selenium, zinc, cadmium, aluminum, gallium, indium, thallium, tin, lead, antimony, bismuth, and tellurium, silver, alloys thereof, or any combination thereof. These metals or metal alloys can be used for manufacturing energy storage devices, and particularly for film stacks for lithium-containing anode structures.

The kiss roller assembly 100 may be contained within a chamber body (not shown) that defines a common processing environment in which some or all of the processing actions for depositing coatings on web materials can be performed. In one or more examples, the common processing environment is operable as a vacuum environment. In other examples, the common processing environment is operable as an inert gas environment. In some examples, the common processing environment can be maintained at a process pressure of about 1×10⁻³ mbar or less, for example, about 1×10⁻⁴ mbar or less.

The kiss roller assembly 100 may be part of a roll-to-roll system, which may include an unwinding reel for supplying a continuous flexible substrate 102, or web, and a winding reel for collecting the continuous flexible substrate 102 after processing. The kiss roller assembly 100 can further include one or more auxiliary transfer reels positioned between the unwinding reel and the winding reel. According to one aspect, at least one of the one or more auxiliary transfer reels, the unwinding reel, and the winding reel can be driven and rotated by a motor. In one or more examples, the motor is a stepper motor. It should be understood that the unwinding reel and the winding reel can be positioned in separate chambers or modules or within the processing region. The unwinding reel and the winding reel can be individually temperature controlled.

In one or more implementations, which can be combined with other implementations, the one or more evaporation assemblies 110, for example, thermal evaporators, can be removably coupled with an evaporation shield (not shown). The one or more thermal evaporation assemblies 110 are positioned to deliver evaporated material onto an outer surface 112 of the kiss roller 106 as the kiss roller rotates with a rotation 108. In one or more implementations, which can be combined with other implementations, the kiss roller 106 is made from a low thermally conductive material and/or a high specific heat material in order to reduce heat transfer to the continuous flexible substrate 102 (e.g., zirconium oxide (e.g., ZrO₂) or quartz (e.g., SiO₂)). In one or more implementations, which can be combined with other implementations, the kiss roller 106 is coated with a thin lithium resistant layer, such as a layer having a thickness of about 0.8 micrometer (μm) to about 1.2 μm (e.g., tungsten, a titanium-zirconium-molybdenum alloy (TZM), molybdenum, any alloy thereof, or any combination thereof ). TZM may include, for example, about 0.5% titanium, about 0.08% zirconium, and about 99.42% molybdenum. In other examples, TZM may contain carbon.

In one or more implementations, which can be combined with other implementations, the kiss roller 106 is about 125 millimeters (mm) in diameter. In one or more implementations, which can be combined with other implementations, the kiss roller 106 is actively temperature controlled such that the continuous flexible substrate 102 is not damaged by the thermal load during processing but the deposition material does not stick to the roller (e.g., in a range from about 150 degrees Celsius to about 200 degrees Celsius, such as in a range from about 185 degrees Celsius to about 190 degrees Celsius or in a range from about 181 to about 200 degrees Celsius).

In one or more implementations, which can be combined with other implementations, the kiss roller 106 is in contact with one or more retractable rollers 104, such as two retractable rollers 104. The one or more retractable rollers 104 keeps the continuous flexible substrate 102 in contact with the outer surface 112 of the kiss roller 106 during substrate processing. In one or more implementations, which can be combined with other implementations, the one or more retractable rollers 104 are actively cooled via liquid flow (e.g., mineral oil) or gas flow (e.g., argon or helium) through an internal diameter of the one or more retractable rollers 104 (e.g., kept at less than or equal to 120 degrees Celsius, such as less than or equal to 80 degrees Celsius). The contact area between the one or more retractable rollers 104 and the outer surface 112 of the kiss roller 106 may be less than or about 10 mm, such as less than or about 7 mm, such as less than or about 4 mm. It is contemplated that the inclusion of more than one retractable roller 104 may allow for an increased contact area between the continuous flexible substrate 102 and the outer surface 112 of the kiss roller 106 which may, in turn, allow for more efficient processing and/or a higher processing rate. In the case of a single retractable roller 104 being used, the roller may be a malleable material with a compliant surface (e.g., a rubber or foam material containing or otherwise made from one or more silicones, one or more fluoroelastomers, one or more fluoropolymers (e.g., a VITON® fluoro material) with a shore A hardness less than 60) such that said surface conforms to the outer surface 112 of the kiss roller 106 and creates a larger contact area.

The kiss roller assembly 100 is positioned to perform one or more processing operations to the continuous flexible substrate 102 or web of material. In one or more examples, as depicted in FIG. 1, the one or more thermal evaporation assemblies 110 are radially disposed about the coating drum 110. In addition, arrangements other than radial are contemplated. In one or more implementations which can be combined with other implementations, the one or more thermal evaporation assemblies 110 can include a lithium source. Further, the one or more thermal evaporation assemblies 110 can also include a source of an alloy of two or more metals. The material to be deposited can be evaporated, for example, by thermal evaporation techniques.

In operation, the one or more thermal evaporation assemblies 110 emit a plume of evaporated material. The evaporated material is drawn to the outer surface 112 of the kiss roller 106 as the kiss roller 106 rotates with rotation 108. The evaporated material forms a thin film (e.g., greater than or equal to about 1 μm thick, such as about 1 μm to about 3 μm thick) of deposited material on the kiss roller 106. The thin film of deposited material is then transferred onto the continuous flexible substrate 102.

In addition, although two thermal evaporation assemblies 110 are shown in FIG. 1, it should be understood that any number of evaporation assemblies 110 can be used. In one or more implementations of the present disclosure which can be combined with other implementations, the kiss roller assembly 100 is configured to process both sides of the continuous flexible substrate 102. Although the kiss roller assembly 100 is configured to process the continuous flexible substrate 102, which is horizontally oriented, the evaporation system 100 can be configured to process substrates positioned in different orientations, for example, the continuous flexible substrate 102 can be vertically oriented. In one or more implementations of the present disclosure which can be combined with other implementations, the continuous flexible substrate 102 is copper, graphite, polyethylene terephthalate (PET), and or some combination thereof.

In one or more implementations of the present disclosure which can be combined with other implementations, a doctor roller (not shown) is positioned in physical contact with the kiss roller 106 after the one or more evaporation assemblies 110 in order to prevent pooling of deposited materials on the outer surface 112 of the kiss roller 106 and ensure a uniform deposition onto the continuous flexible substrate 102.

FIG. 2 illustrates a method 200 for depositing material on a substrate, such as the substrate 102 of FIG. 1, in a roll-to-roll vacuum system according to one or more embodiments. Operation 202 includes depositing a first layer with a first thickness on a substrate, such as the substrate 102 of FIG. 1, using a first evaporation assembly. Operation 204 includes evaporating a fluid (e.g., lithium) onto a kiss roller, such as the kiss roller 106 of FIG. 1, using a second evaporation assembly, such as the evaporation assembly 110 of FIG. 1. Operation 206 includes depositing a second layer with a second thickness on the substrate via the kiss roller. In one or more implementations, which can be combined with other implementations, the second thickness is greater than the first thickness.

In one or more implementations of the present disclosure which can be combined with other implementations, the kiss roller assembly 100 further includes a system controller (not shown) operable to control various aspects of the kiss roller system 100. The system controller may facilitate the control and automation of the kiss roller system 100 and can include a central processing unit (CPU), memory, and support circuits (or I/O). Software instructions and data can be coded and stored within the memory for instructing the CPU. The system controller can communicate with one or more of the components of kiss roller system 100 via, for example, a system bus. A program (or computer instructions) readable by the system controller determines which tasks are performable on a substrate. In some aspects, the program is software readable by the system controller, which can include code for monitoring chamber conditions, including independent temperature control of the one or more chamber components. It should be appreciated that multiple system controllers can be used with the aspects described herein.

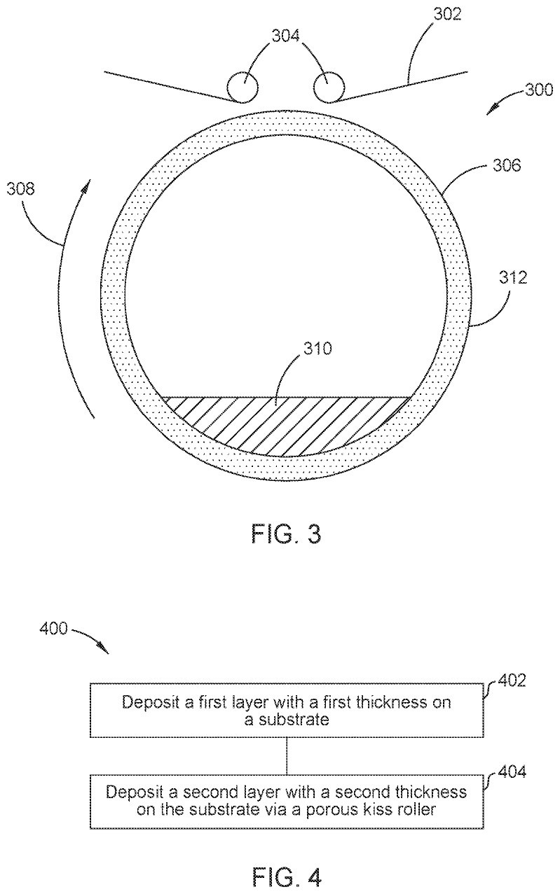

FIG. 3 illustrates a schematic side view of a kiss roller assembly 300 having a porous kiss roller 306 according to one or more embodiments. The kiss roller assembly 300 can be part of a roll-to-roll system adapted for depositing coatings on web materials, for example, for depositing metal containing film stacks according to the implementations described herein. In one or more examples, the kiss roller assembly 300 can be used for depositing elemental metals, metal alloys, and/or other elements. Examples of metal elements, metal alloys, and other elements can be or include alkali metals (e.g., lithium or sodium), alkaline earth metals (e.g., magnesium or beryllium), selenium, zinc, cadmium, aluminum, gallium, indium, thallium, tin, lead, antimony, bismuth, and tellurium, silver, alloys thereof, or any combination thereof. These metals or metal alloys can be used for manufacturing energy storage devices, and particularly for film stacks for lithium-containing anode structures.

The kiss roller assembly 300 may be contained within a chamber body (not shown) that defines a common processing environment in which some or all of the processing actions for depositing coatings on web materials can be performed. In one or more examples, the common processing environment is operable as a vacuum environment. In other examples, the common processing environment is operable as an inert gas environment. In some examples, the common processing environment can be maintained at a process pressure of about 1×10⁻³ mbar or less, for example, about 1×10⁻⁴ mbar or less.

The kiss roller assembly 300 may be part of a roll-to-roll system, which may include an unwinding reel for supplying a continuous flexible substrate 302, or web, and a winding reel for collecting the continuous flexible substrate 302 after processing. The kiss roller assembly 100 can further include one or more auxiliary transfer reels positioned between the unwinding reel and the winding reel. According to one aspect, at least one of the one or more auxiliary transfer reels, the unwinding reel, and the winding reel can be driven and rotated by a motor. In one or more examples, the motor is a stepper motor. It should be understood that the unwinding reel and the winding reel can be positioned in separate chambers or modules or within the processing region. The unwinding reel and the winding reel can be individually temperature controlled.

In one or more implementations, which can be combined with other implementations, the porous kiss roller 306 has an outer surface 312 and contains a molten bath 310. In one or more implementations, which can be combined with other implementations, the porous kiss roller 306 is made from a metal or metal alloy (e.g., stainless steel, molybdenum, tungsten). In one or more implementations, which can be combined with other implementations, the porous kiss roller 306 is coated with a thin lithium resistant layer, such as a layer having a thickness of about a 0.8 micrometer (μm) to about a 1.2 μm (e.g., tungsten, a titanium-zirconium-molybdenum alloy (TZM), molybdenum, any alloy thereof, or any combination thereof). TZM may include, for example, about 0.5% titanium, about 0.08% zirconium, and about 99.42% molybdenum. In other examples, TZM may contain carbon.

In one or more implementations, which can be combined with other implementations, the porous kiss roller 306 is about 125 mm in diameter. In one or more implementations, which can be combined with other implementations, the porous kiss roller 306 is actively temperature controlled such that the continuous flexible substrate 302 is not damaged by the thermal load during processing (e.g., in a range from about 150 degrees Celsius to about 200 degrees Celsius, such as in a range from about 185 degrees Celsius to about 190 degrees Celsius or in a range from about 181 to about 200 degrees Celsius).

In one or more implementations, which can be combined with other implementations, the porous kiss roller 306 is in contact with one or more retractable rollers 304, such as two retractable rollers 304. The one or more retractable rollers 304 keeps the continuous flexible substrate 302 in contact with the outer surface 312 of the porous kiss roller 306 during substrate processing. In one or more implementations, which can be combined with other implementations, the one or more retractable rollers 304 are actively cooled (e.g., kept at less than or equal to about 100 degrees Celsius). The contact area between the one or more retractable rollers 304 and the outer surface 312 of the porous kiss roller 306 may be less than or about 10 mm, such as less than or about 7 mm, such as less than or about 4 mm. It is contemplated that the inclusion of more than one retractable roller 304 may allow for an increased contact area between the continuous flexible substrate 302 and the outer surface 312 of the kiss roller 306 which may, in turn, allow for more efficient processing and/or a higher processing rate. In the case of a single retractable roller 104 being used, the roller may be a malleable material with a compliant surface such that said surface conforms to the outer surface 312 of the porous kiss roller 306 and creates a larger contact area.

The kiss roller assembly 300 is positioned to perform one or more processing operations to the continuous flexible substrate 302 or web of material. In operation, the fluid bath 310 contains a molten material (e.g., molten lithium) which is drawn to the outer surface 312 of the porous kiss roller 306 as it rotates with rotation 308 through capillary action and a thin film (e.g. greater than or equal to about 1 μm thick, such as about 1 μm to about 20 μm thick, such as less than 10 μm thick) of deposited material is formed. The thin film of molten material is then transferred onto the continuous flexible substrate 302. The thickness of the transferred material layer onto the continuous flexible substrate 302 from the outer surface 312 of the porous kiss roller 306 is dependent on the porosity of the porous kiss roller 306. In one or more implementations, which can be combined with other implementations, the porosity of the porous kiss roller is in a range from about 2 μm to about 100 μm, such as in a range from about 20 μm to about 60 μm, such as about 40 μm.

In one or more implementations of the present disclosure which can be combined with other implementations, the kiss roller assembly 100 is configured to process both sides of the continuous flexible substrate 302. Although the kiss roller assembly 300 is configured to process the continuous flexible substrate 302, which is horizontally oriented, the evaporation system 100 can be configured to process substrates positioned in different orientations, for example, the continuous flexible substrate 302 can be vertically oriented. In one or more implementations of the present disclosure which can be combined with other implementations, the continuous flexible substrate 302 is copper, graphite, PET, and or some combination thereof.

In one or more implementations of the present disclosure which can be combined with other implementations, a doctor roller (not shown) is positioned in physical contact with the kiss roller 306 before the continuous flexible substrate 302 in order to prevent pooling of deposited materials on the outer surface 312 of the kiss roller 306 and ensure a uniform deposition onto the continuous flexible substrate 302.

FIG. 4 illustrates a method 400 for depositing material on a substrate, such as the substrate 302 of FIG. 3, in a roll-to-roll vacuum system according to one or more embodiments. Operation 402 includes depositing a first layer with a first thickness on a substrate, such as the substrate 302 of FIG. 3, using an evaporation assembly. Operation 404 includes depositing a second layer with a second thickness on the substrate via a porous kiss roller, such as the porous kiss roller 306 of FIG. 3. In one or more implementations, which can be combined with other implementations, the second thickness is greater than the first thickness. In one or more implementations of the present disclosure which can be combined with other implementations, the kiss roller assembly 100 further includes a system controller (not shown) operable to control various aspects of the kiss roller system 300. The system controller may facilitate the control and automation of the kiss roller system 300 and can include a central processing unit (CPU), memory, and support circuits (or I/O). Software instructions and data can be coded and stored within the memory for instructing the CPU. The system controller can communicate with one or more of the components of kiss roller system 300 via, for example, a system bus. A program (or computer instructions) readable by the system controller determines which tasks are performable on a substrate. In some aspects, the program is software readable by the system controller, which can include code for monitoring chamber conditions, including independent temperature control of the one or more chamber components. It should be appreciated that multiple system controllers can be used with the aspects described herein.

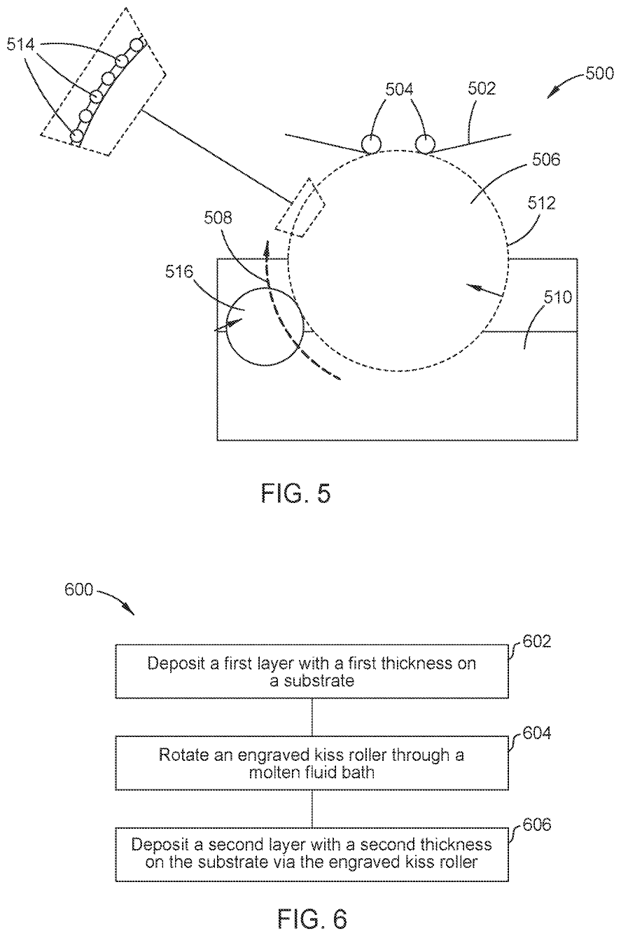

FIG. 5 illustrates a schematic side view of a kiss roller assembly 500 having an engraved kiss roller 506 according to one or more embodiments. The kiss roller assembly 500 can be part of a roll-to-roll system adapted for depositing coatings on web materials, for example, for depositing metal containing film stacks according to the implementations described herein. In one or more examples, the kiss roller assembly 500 can be used for depositing elemental metals, metal alloys, and/or other elements. Examples of metal elements, metal alloys, and other elements can be or include alkali metals (e.g., lithium or sodium), alkaline earth metals (e.g., magnesium or beryllium), selenium, zinc, cadmium, aluminum, gallium, indium, thallium, tin, lead, antimony, bismuth, and tellurium, silver, alloys thereof, or any combination thereof. These metals or metal alloys can be used for manufacturing energy storage devices, and particularly for film stacks for lithium-containing anode structures.

The kiss roller assembly 500 may be contained within a chamber body (not shown) that defines a common processing environment in which some or all of the processing actions for depositing coatings on web materials can be performed. In one or more examples, the common processing environment is operable as a vacuum environment. In other examples, the common processing environment is operable as an inert gas environment. In some examples, the common processing environment can be maintained at a process pressure of about 1×10⁻³ mbar or less, for example, about 1×10⁻⁴ mbar or less.

The kiss roller assembly 500 may be part of a roll-to-roll system, which may include an unwinding reel for supplying a continuous flexible substrate 502, or web, and a winding reel for collecting the continuous flexible substrate 502 after processing. The kiss roller assembly 500 can further include one or more auxiliary transfer reels positioned between the unwinding reel and the winding reel. According to one aspect, at least one of the one or more auxiliary transfer reels, the unwinding reel, and the winding reel can be driven and rotated by a motor. In one or more examples, the motor is a stepper motor. It should be understood that the unwinding reel and the winding reel can be positioned in separate chambers or modules or within the processing region. The unwinding reel and the winding reel can be individually temperature controlled.

In one or more implementations, which can be combined with other implementations, the engraved kiss roller 506 is partially submerged in a molten bath 510. In one or more implementations, which can be combined with other implementations, the molten bath 510 contains a molten lithium. In one or more implementations, which can be combined with other implementations, the engraved kiss roller 506 is made from metal or metal alloy.

In one or more implementations, which can be combined with other implementations, the engraved kiss roller 506 is about 125 mm in diameter. In one or more implementations, which can be combined with other implementations, the engraved kiss roller 506 is actively temperature controlled such that the continuous flexible substrate 502 is not damaged by the thermal load during processing but the deposition material does not stick to the roller (e.g., in a range from about 150 degrees Celsius to about 200 degrees Celsius, such as in a range from about 185 degrees Celsius to about 190 degrees Celsius or in a range from about 181 to about 200 degrees Celsius).

In one or more implementations, which can be combined with other implementations, the engraved kiss roller 506 is in contact with one or more retractable rollers 504, such as two retractable rollers 504. The one or more retractable rollers 504 keeps the continuous flexible substrate 502 in contact with an outer surface 512 of the engraved kiss roller 506 during substrate processing. In one or more implementations, which can be combined with other implementations, the one or more retractable rollers 504 are actively cooled (e.g., kept at less than or equal to about 100 degrees Celsius). The contact area between the one or more retractable rollers 504 and the outer surface 512 of the engraved kiss roller 506 may be less than or about 10 mm, such as less than or about 7 mm, such as less than or about 4 mm. It is contemplated that the inclusion of more than one retractable roller 504 may allow for an increased contact area between the continuous flexible substrate 502 and the outer surface 512 of the kiss roller 506 which may, in turn, allow for more efficient processing and/or a higher processing rate. In the case of a single retractable roller 504 being used, the roller may be a malleable material with a compliant surface such that said surface conforms to the outer surface 512 of the engraved kiss roller 506 and creates a larger contact area.

The kiss roller assembly 500 is positioned to perform one or more processing operations to the continuous flexible substrate 502 or web of material. In operation, the engraved kiss roller 506 rotates with a rotation 508 and engraved portions 514 of the engraved kiss roller 506 pick-up molten material at a desired thickness and a thin film (e.g. greater than or equal to about 1 μm thick, such as about 1 μm to about 3 μm thick) of deposited material is formed. The thin film of deposited material is then transferred onto the continuous flexible substrate 502. In one or more implementations, which can be combined with other implementations, the depth of the engraved portions 514 of the engraved kiss roller 506 are in a range from about 1 μm to about 50 μm, such as in a range from about 10 μm to about 40 μm, such as in a range from about 20 μm to about 30 μm. It is contemplated that the depth of the engraved portions 514 of the engraved kiss roller 506 may be changed in order to obtain a desired film thickness.

In one or more implementations of the present disclosure which can be combined with other implementations, the kiss roller assembly 500 is configured to process both sides of the continuous flexible substrate 502. Although the kiss roller assembly 500 is configured to process the continuous flexible substrate 502, which is horizontally oriented, the evaporation system 100 can be configured to process substrates positioned in different orientations, for example, the continuous flexible substrate 502 can be vertically oriented. In one or more implementations of the present disclosure which can be combined with other implementations, the continuous flexible substrate 502 is copper, graphite, PET, and or some combination thereof.

In one or more implementations of the present disclosure which can be combined with other implementations, a doctor roller 516 is positioned in physical contact with the kiss roller 506 after the molten bath 510 in order to prevent pooling of deposited materials on the outer surface 512 of the engraved kiss roller 506 and ensure a uniform deposition onto the continuous flexible substrate 502.

FIG. 6 illustrates a method 600 for depositing material on a substrate, such as the substrate 502 of FIG. 5, in a roll-to-roll vacuum system according to one or more embodiments. Operation 602 includes depositing a first layer with a first thickness on a substrate, such as the substrate 502 of FIG. 5, via an evaporation assembly. Operation 604 includes rotating an engraved kiss roller, such as the engraved kiss roller 506 of FIG. 5, through a molten fluid bath, such as the molten bath 510 of FIG. 5. Operation 606 includes depositing a second layer with a second thickness on the substrate via the engraved kiss roller. In one or more implementations, which can be combined with other implementations, the second thickness is greater than the first thickness. In one or more implementations of the present disclosure which can be combined with other implementations, the kiss roller assembly 500 further includes a system controller (not shown) operable to control various aspects of the kiss roller system 500. The system controller may facilitate the control and automation of the kiss roller system 100 and can include a central processing unit (CPU), memory, and support circuits (or I/O). Software instructions and data can be coded and stored within the memory for instructing the CPU. The system controller can communicate with one or more of the components of kiss roller system 500 via, for example, a system bus. A program (or computer instructions) readable by the system controller determines which tasks are performable on a substrate. In some aspects, the program is software readable by the system controller, which can include code for monitoring chamber conditions, including independent temperature control of the one or more chamber components. It should be appreciated that multiple system controllers can be used with the aspects described herein.

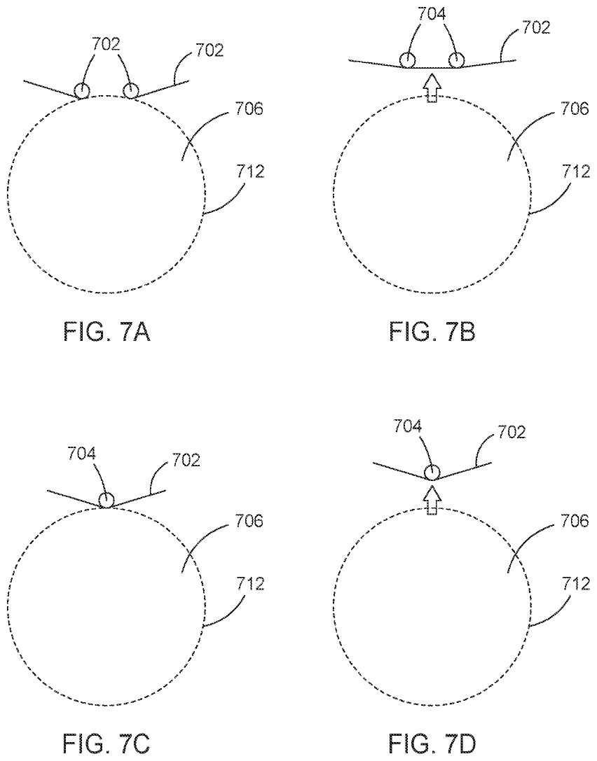

FIGS. 7A-7D illustrate a schematic side view of a kiss roller assembly 700 having one or more retractable rollers 704 according to one or more embodiments. As shown in FIGS. 7A-7B two retractable rollers 704 may be retracted such that the two retractable rollers 704 are no longer in contact with an outer surface 712 of a kiss roller 706. As shown in FIGS. 7C-7D a single retractable roller 704 may be retracted such that the retractable roller 704 is no longer in contact with the outer surface 712 of the kiss roller 706.

Implementations can include one or more of the following potential advantages. The use of thermal evaporators for an initial pre-lithiation allow for the kiss roller assembly to wet out and freeze onto the substrate and not bead up. Such beading would cause a non-uniform coating. Furthermore, the use of the kiss roller embodiments herein allow for the thicker (e.g., greater than or about 1 μm thick) film with good edge isolation and uniformity. Further, the use of the kiss roller embodiments herein may also lead to the ability to process the cold substrate more quickly without overheating the substrate when compared to a hot processing system with molten lithium and/or relatively hot highly thermally conductive kiss rollers.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, e.g., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

1. A roll-to-roll vacuum coating system, comprising:
a substrate;
a first evaporation assembly; and
a kiss roller assembly comprising:
a kiss roller with a thermal conductivity of less than or equal to 30 W/m-K;
a second evaporation assembly; and at least one retractable roller.

2. The roll-to-roll vacuum coating system of claim 1, wherein the kiss roller is made from zirconium oxide.

3. The roll-to-roll vacuum coating system of claim 1, wherein the kiss roller is made from aluminum oxide.

4. The roll-to-roll vacuum coating system of claim 1, wherein the kiss roller is made from silicon oxide.

5. The roll-to-roll vacuum coating system of claim 1, wherein the kiss roller is coated with tungsten, molybdenum, a titanium-zirconium-molybdenum alloy, any alloy thereof, or any combination thereof.

6. The roll-to-roll vacuum coating system of claim 1, wherein the at least one retractable roller includes two retractable rollers.

7. The roll-to-roll vacuum coating system of claim 1, wherein the at least one retractable roller is configured to be actively cooled to less than or equal to about 100 degrees Celsius.

8. The roll-to-roll vacuum coating system of claim 1, further comprising a doctor roller in physical contact with the kiss roller.

9-14. (canceled)

15. A roll-to-roll vacuum coating system, comprising:
a substrate;
an evaporation assembly radially disposed about a coating drum; and
a kiss roller assembly, comprising:
a porous kiss roller; and
at least one retractable roller.

16. The roll-to-roll vacuum coating system of claim 15, wherein there are two retractable rollers.

17. The roll-to-roll vacuum coating system of claim 15, wherein the at least one retractable roller is configured to be actively cooled to less than or equal to about 100 degrees Celsius.

18. The roll-to-roll vacuum coating system of claim 15, further comprising a doctor roller in physical contact with the porous kiss roller.

19. The roll-to-roll vacuum coating system of claim 15, wherein the porous kiss roller has a porosity of about 40 μm.

20-25. (canceled)

26. A roll-to-roll vacuum coating system, comprising: a substrate;
an evaporation assembly radially disposed about a coating drum; and
a kiss roller assembly, comprising:
an engraved kiss roller with engraved portions;
a molten fluid bath; and
at least one retractable roller.

27. The roll-to-toll vacuum coating system of claim 26, wherein the molten fluid bath comprises molten lithium.

28. The roll-to-roll vacuum coating system of claim 26, wherein the at least one retractable roller has two retractable rollers.

29. The roll-to-roll vacuum coating system of claim 26, wherein the at least one retractable roller is actively cooled to less than or equal to about 100 degrees Celsius.

30. The roll-to-roll vacuum coating system of claim 26, further comprising a doctor roller in physical contact with the engraved kiss roller.

31. The roll-to-roll vacuum coating system of claim 26, wherein the engraved portions have a depth in a range of about 2 μm to about 50 μm.

32-38. (canceled)

39. The roll-to-roll vacuum coating system of claim 26, wherein the kiss roller assembly further comprises at least one retractable roller that is actively cooled to less than or equal to about 100 degrees Celsius.
